(19) United States
(12) Patent Application Publication
(10) Pub. No.: US 2002/0105081 A1
(43) Pub. Date: Aug. 8, 2002

(54) Self-assembled near-zero-thickness molecular layers as diffusion barriers for Cu metallization

(76) Inventors: G. Ramanath, Clifton Park, NY (US); Ahila Krishnamoorthy, Madras (IN); Kaushik Chanda, Poughkeepsie, NY (US); Shyam P. Murarka, Clifton Park, NY (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/977,069

(22) Filed: Oct. 11, 2001

Related U.S. Application Data
(60) Provisional application No. 60/240,109, filed on Oct. 12, 2000.
(60) Provisional application No. 60/244,160, filed on Oct. 27, 2000.
(60) Provisional application No. 60/255,100, filed on Dec. 12, 2000.

(51) Int. Cl. H01L 21/44; H01L 23/48; H01L 23/52; H01L 29/40

(52) U.S. Cl. 257/751; 438/653; 438/681; 438/687

(57) ABSTRACT

The present invention provides a diffusion barrier in an integrated circuit. The diffusion barrier comprises a self-assembled monolayer. The diffusion barrier is preferably less than 5 nm thick; more preferably it is less than 2 nm thick. The self-assembled monolayer typically contains an aromatic group at its terminus.

### RELATED CASES

This application is related to and claims priority to provisional Applications Nos. 60/240,109 entitled Diffusion Barriers Comprising A Self-Assembled Monolayer naming G. Ramanath, Ahila Krishnamoorthy, Kaushik Chanda and Shyarm P. Murarka as inventors and filed Oct. 12, 2000, 60/244,160 entitled Diffusion Barriers Comprising A Self-Assembled Monolayer naming G. Ramanath, Ahila Krishnamoorthy, Kaushik Chanda and Shyarm P. Murarka as inventors and filed Oct. 27, 2000, and 60/255,100 entitled Self-Assembled Near-Zero-Thickness Molecular Layers As Diffusion Barriers For Cu Metallization naming G. Ramanath, Ahila Krishnamoorthy, Kaushik Chanda and Shyarm P. Murarka as inventors and filed Dec. 12, 2000. These applications are incorporated herein for all purposes as if set forth herein in full.

### STATEMENT AS TO RIGHTS TO INVENTIONS MADE UNDER FEDERALLY SPONSORED RESEARCH OR DEVELOPMENT

The US Government may have certain rights in this invention pursuant to National Science Foundation CAREER grant DMR-9984478.

### REFERENCE TO A “SEQUENCE LISTING,” A TABLE, OR A COMPUTER PROGRAM LISTING APPENDIX SUBMITTED ON A COMPACT DISK

Not Applicable

### BACKGROUND OF THE INVENTION

A. Field of the Invention

The present invention generally relates to integrated circuits. In particular, it relates to forming a diffusion barrier layer comprising a self-assembled monolayer in an integrated circuit.

B. Description of Related Art

Copper is becoming the metal of choice for forming conductive patterns in integrated circuits. There are, however, unresolved issues with its use. For instance, copper diffuses rapidly in silicon and silicon dioxide. The diffusion, over time, results in junction linkage, which decreases device efficiency.

To address the problem of copper diffusion, researchers have developed “diffusion barriers.” A diffusion barrier is part of the metallization scheme, comprising a layer of material formed between an overlying copper layer and an underlying silicon or silicon dioxide layer. The diffusion barrier serves to inhibit the diffusion of copper into the surrounding layer.

The use of amorphous alloys as diffusion layers has been discussed. Amorphous binary silicides, such as molybdenum-, tantalum and tungsten silicide and amorphous ternary alloys (e.g., Ti—Si—N) have been reported as diffusion barriers. The formation of these layers, however, uses sophisticated sputtering processes and results in the inclusion of substantial contaminants.

Diffusion barriers made of TiN, TiSiN and TiN/TiSiN have also been reported. The titanium was deposited by sputtering in the presence of ammonia, which was used as a nitridation agent. A two-step annealing process completed the layer formation.

While a number of diffusion barriers have been discussed in the art, improved diffusion barriers are always desirable, especially diffusion barriers that are formed in very thin layers.

### SUMMARY OF THE INVENTION

The present invention provides a diffusion barrier in an integrated circuit. The diffusion barrier comprises a self-assembled monolayer. The diffusion barrier is preferably less than 5 nm thick; more preferably it is less than 2 mn thick. The self-assembled monolayer typically contains an aromatic group at its terminus.

### BRIEF DESCRIPTION OF THE DRAWINGS

FIG. 1 shows representative C-V curves from a control sample (open legends) and a SAM1-coated MOS structure (filled legends) obtained prior to BTA, and at failure.

FIG. 2 shows (a) flat band voltage shift, AVFB and (b) leakage current density, leakage, plotted as a function of tBTA for control and SAMI -coated samples.

FIG. 3 shows a box plot of the failure times of MOS structures with the different SAMs at the Cu/SiO₂ interface. The boxes edges represent the upper and lower quartile value, the error bars show the maximum and the minimum, and the central line indicates the median failure time.

### DESCRIPTION OF THE SPECIFIC EMBODIMENTS

Devising ultra-thin barrier layers to prevent Cu diffusion into SiO₂-based dielectrics is a major challenge that must be met to increase the speed, number density, and performance of microelectronics devices. Here, we demonstrate the use of near-zero-thickness (<2-nm-thick) self-assembled monolayers (SAMs) as barriers to Cu diffusion into SiO₂. Cu/SiO₂/Si(001-metal-oxide-semiconductor (MOS) capacitors, with and without SAMs at the Cu/SiO₂ interface, were annealed at 200° C. in a 2 MV cm⁻¹ electrical field. Capacitance-voltage (C-V) and current-voltage (I-V) measurements of MOS capacitors coated with SAMs having aromatic terminal groups consistently show as much as 5-orders-of-magnitude lower leakage currents and a factor-of-4 higher time to failure when compared with the corresponding values from uncoated interfaces. SAMs with short tail lengths or aliphatic terminal groups are ineffective in hindering Cu diffusion, indicating that the molecular length and chemical configuration are key factors determining the efficacy of SAMs as barriers. We propose that the steric hindrance offered by the terminal groups in the SAMs are responsible for the barrier properties.

Copper is the preferred metal for creating multilevel interconnect structures in ultra-large-scale-integrated (ULSI) circuits because of its high electrical conductivity and electromigration resistance. (S. P. Murarka, Mater. Sci. Eng. R19, 87-151 (1997).) One of the challenges in Cu metallization technology is to prevent the rapid diffusion of Cu into SiO₂ under an electrical bias during device operation. This is because Cu incorporation degrades the dielectric properties of the oxide layer, causing leakage currents and leading to inferior device performance and failure. (J. D. McBrayer, R. M. Swanson, and T. W. Signmon, J. Electrochecm. Soc. 133, 1243 (1986).) Furthermore, the use of many low dielectric-constant materials such as fluorinated SiOₓ is critical for achieving greater device speeds. (W. Chang, S. M. Jang, C. H. Yu, S.C. Sun, and M. S. Liang, San Francisco, Calif., USA, 1999 (IEEE, Piscataway, NJ), p. 295, 131-3; G. S. Chen and S. T. Chen, J. Appl. Phys. 87, 8473 (2000).) It is thus crucial to devise solutions to prevent Cu diffusion across SiOₓ-based materials.

Several researchers have advocated the use of ≅10 to 30 -nm-thick diffusion barrier layers of Ti- or Ta-based compounds or Cu-based alloys to alleviate this problem. (C. Ahrens, D. Depta, F. Schitthelm, and S. Wilhelm, Appl. Surf. Sci. 91, 285-90 (1995); P. J. Ding, W. A. Lanford, S. Hymes, and S. P. Murarka, Appl. Phys. Lett. 64, 2897 (1994); and, P. J. Ding, W. A. Lanford, S. Hymes, and S. P. Murarka, Appl. Phys. 75, 3627 (1994).) While this approach has been successful thus far, new types of barriers are likely to be needed at device dimensions below 100 nm in contemporary device architectures, and very high-aspect ratio structures in 3D-integration of multiple-wafer devices. The barrier layer thickness should be kept below 5 nm for future devices to fully realize the advantage of high conductivity Cu. This is difficult to achieve by conventional physical and chemical vapor deposition methods without compromising either conformal coverage of high aspect ratio features and/or the barrier layer microstructure, both of which reduce the efficacy of the barrier. (A. Z. Moshfegh and O. Akhavan, Thin Solid Films 370, 10 (2000); A. Sekiguchi, J. Koike, and K. Maruyama, J. Japan Inst. Metals 64, 379 (2000).)

In this letter, we demonstrate for the first time that certain types of SAMs with typical lengths of <2 nm can serve as barriers for device applications. SAMs have near-zero thicknesses (NZT) and, by definition, will occupy an insignificant fraction of the total via/hole volume, thereby maximizing the room for filling in low-resistivity Cu. SAMs are expected to have good step coverage on high-aspect ratio features due to their high sticking probability with the substrate and low probability of depositing on themselves. Measurements also indicate that these monolayers may promote adhesion of Cu to dielectric surfaces. (L. Klapp, A. Krishnamoorthy, S. P. Murarka, and G. Ramanath, Unpublished (2000).) Moreover, the molecular dimensions of SAM also make them attractive for molecular electronics applications. (M. A. Reed and J. M. Tour, Scientific American 282, 86 (2000).)

Cu/SiO₂/Si and Cu/SAM/SiOs/Si metal-oxide-semiconductor (MOS) structures were fabricated from p-and n-type device-quality Si(001) wafers capped with a 85-nm-thick dry-thermal oxide. The back-oxide was stripped using HF, and a 500-nm-thick Al back-contact was deposited by DC magnetron sputtering in an Ar plasma at 5 mTorr. The chamber base pressure was 9×10⁻⁷ Torr. The samples were annealed in a 2×10⁻⁷ Torr vacuum at 450° C. to ensure the formation of an ohmic contact. These substrates were successively rinsed in ultrasonic baths of xylene, acetone, isopropanol and deionized water, and dried with N₂ to provide a clean surface for assembling the monolayers. The SAMs were deposited (see below) on one half of the wafer and the other half was used to make the control sample.

Organosilane compounds dissolved in toluene to obtain a 1% solution were used to form SAMs on SiO₂ by the procedure described by Dressick et al. (W. J. Dressick, C. S. Dulcey, J. H. Georger, G. S. Calabrese, and J. M. Calvert, J. Electrochem. Soc. 141, 210 (1994).) The samples were then washed with toluene and baked for 4 minutes at 120° C. In all the SAMs, the trimethoxysilane group (Si with three —OCH₃ groups) is tethered to the SiO₂ substrate, while the fourth Si bond is attached to a tail consisting of aliphatic and/or aromatic groups (see Table 1). Finally, a 1000 -nm-thick Cu film was sputter-deposited in Ar at 5 mTorr through a shadow mask to form 1.2 -mm-dia gate contacts of the MOS capacitors.

Small samples with 3×3 dot arrays sliced from the wafers were used for thermal annealing at 200° C. and an electric field of 2 MV/cm in flowing N₂— the treatment is referred to as bias thermal annealing (BTA). Capacitance-voltage (C-V) and current-voltage (I-V) characteristics were measured at 30-minute intervals using HP 4280 AC and HP4140 pA DC instruments, respectively, after rapidly cooling the samples to room temperature prior to each measurement. The C-V and I-V responses without any electrical bias were also measured before BTA. The measurements were continued until the sample failed; the failure criterion being defined as leakage current density j_{leakage}>1000 nA cm⁻² at −40 V gate voltage.

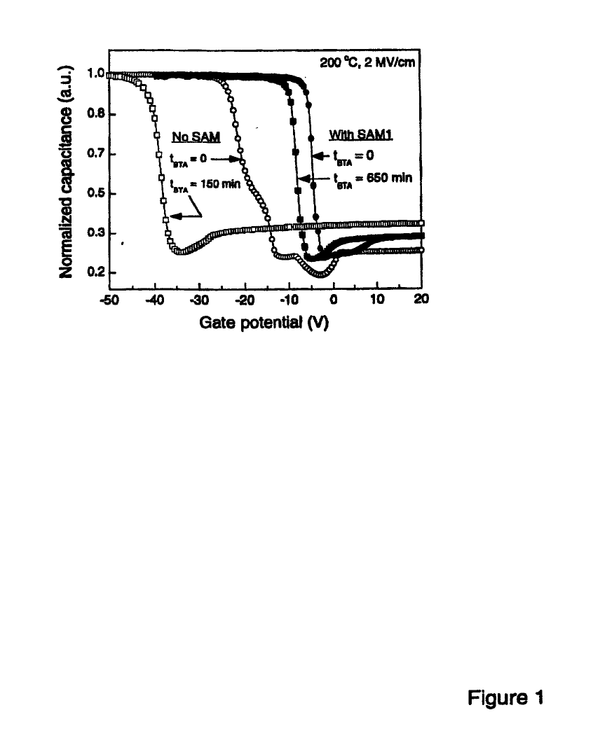

Several reports have shown that the shift in the flat-band voltage V^{FB} and the increase in leakage current j_{leakage} are characteristic signatures of Cu ion diffusion and incorporation into SiO₂.² Comparison of the C-V and I-V characteristics of our MOS structures with and without SAM at the Cu/SiO₂. FIG. 1 shows a typical normalized-capacitance (C/Cₘₐₓᵢₘᵤₘ) vs. gate voltage plots for a control sample and a SAM1-coated MOS structure prior to BTA (annealing time t_{BTA}=0 min), and at failure-defined by j_{leakage}>1000 nA cm⁻². The flat-band voltage of the control sample V^{FB}_{control} shifts to lower values with increasing t_{BTA}, indicating Cu ion diffusion. The control samples failed at t_{BTA}≅150 min, corresponding to a flat-band voltage shift of ΔV^{FB}_{control}≅18 V. At the same t_{BTA}, SAM1-coated samples showed ΔV^{FB}_{SAM}<1.5 V and j_{leakage}<30 nA cm

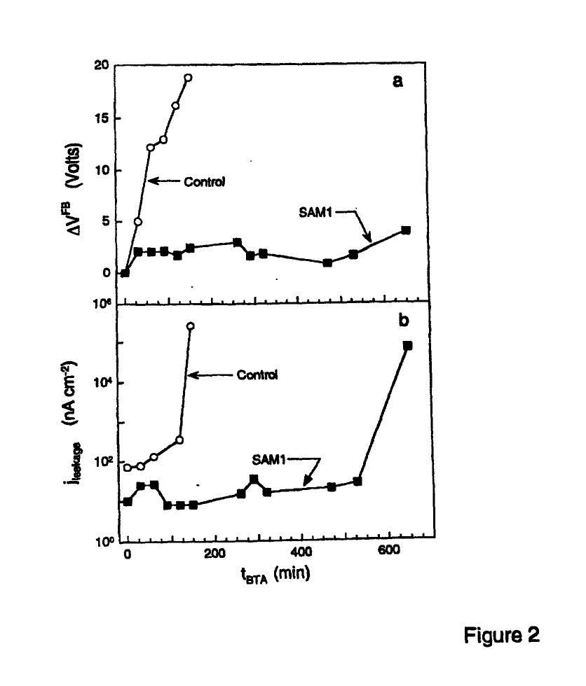

2 (see FIG. 2), and failed only at t_{BTA}≅650 min—a four-fold increase in the time to failure.

FIG. 2a shows ΔV^{FB} plotted as a function of t_{BTA} for control and SAM1-coated samples. ΔV^{FB}_{control} increases with t_{BTA} rapidly [d(ΔV^{FB})/dt˜0.11 V min⁻¹], and continuously, all the way to failure. But, ΔV^{FB}_{SAM} remains relatively unchanged at ≅1.5 V with only a marginal increase of ≅0.0029 V cm⁻¹ until failure, at which point ΔV^{FB}_{SAM} increases to ≅5V. The leakage current density j_{leakage} also shows similar characteristics as ΔV^{FB} (see FIG. 2b). In the control sample, j_{leakage} continuously increases at a rapid rate, while in the SAM-coated sample a relatively constant j_{leakage} value of ≅10-30 nA cm⁻² persists right until failure, when it abruptly shoots up to values >10⁵ nA cm⁻². We note that at t_{BTA} corresponding to the failure of the control sample, j_{leakage} in SAM1-coated samples is more than four orders of magnitude smaller at ≅10 nA cm⁻².

The above results clearly indicate that SAM1 effectively hinders Cu diffusion into SiO₂. In the control sample Cu diffuses continuously during the BTA treatment and the continued Cu ion accumulation in the oxide layer causes monotonically increasing leakage currents, and finally failure. In the SAM1-coated samples, Cu diffusion is negligible for much longer times, and at failure, the leakage current increases catastrophically.

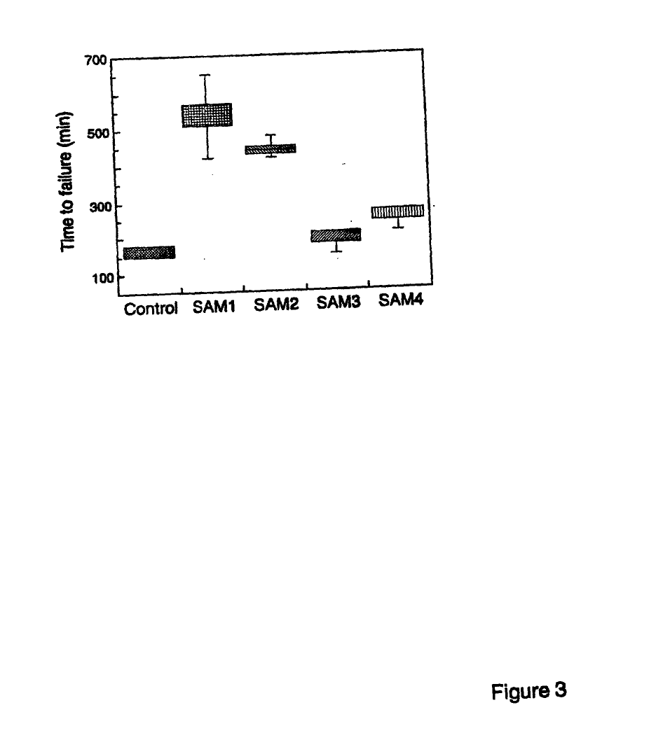

In order to obtain insights into the mechanism by which SAM1 prevents Cu diffusion into SiO₂, we investigated the barrier properties SAMs with different molecular lengths and terminal groups (see Table 1). FIG. 3 is a box plot that summarizes the failure times of MOS structures with the different SAMs at the Cu/SiO₂ interface. Our results indicate that both the molecular chain length and the terminal group are important factors that determine the barrier properties of SAMs. MOS capacitors with SAM1 and SAM2, both of which are terminated by aromatic rings—pyridyl and phenyl, respectively—show longer failure times. The slightly higher average failure time in samples with SAM1 is probably due to enhanced interaction of Cu with the N in the pyridyl ring. (S. Kotrly and L. Sucha, Handbook of Chemical Equilibria in Analytical Chemistry (Ellis Horwood Limited, Chichester, 1985).) The average failure times of MOS capacitors with SAM3, which has an aliphatic terminal group, is similar to that of the control samples. These results indicate that the aromatic terminal group plays an important role in preventing Cu diffusion into SiO₂. MOS structures with SAM4—shortest length compared to the other SAMs, but has an aromatic terminal group—exhibit only a marginally greater failure time than the control sample, indicating that SAMs with longer chains are better barriers.

Based upon our results, the barrier properties of SAMs can be explained in terms of the size and configuration of the terminal group, and the molecular chain length. We propose that the larger volume (compared with, for example, aliphatic groups) occupied by the aromatic rings sterically hinder Cu diffusion between the molecules through the SAM layer. SAMs with long chain lengths will screen Cu atoms from the influence of the SiO₂ substrate, thereby preventing ionization and consequent acceleration by the externally applied electric field. The Si—(OCH₃)₃ head group is unlikely to play any significant role in hampering Cu diffusion because the Si—O—Si linkages they form—to tether the SAMs to the substrate—are similar to those in SiO₂. While the mechanism by which the SAMs eventually fail is not clear from our experiments, the probable cause is the development of defects such as pinholes at the interface. (E. E. Polymeropoulos, J. Appl. Phys. 48, 2404 (1977); D. Vuillaume, C. Boulas, J. Collet, J. V. Davidovits, and F. Rondelez, Appl. Phys. Lett. 69, 1646 (1996).)

In summary, we have shown that self-assembled monolayers of organosilane molecules can inhibit Cu diffusion into SiO₂ during bias thermal annealing. The size and configuration of the terminal functional group, and the chain length of the SAMs, are two important factors that determine barrier properties. SAMs are attractive for Cu-based microelectronics circuits because of their near-zero-thickness, good conformality, and facile processing.

| Molecule | Chemical formula | IUPAC Name |
|---|---|---|
| SAM1 | 1 | 3-[2-(trimethoxysilyl)ethyl]pyridine |
| SAM2 | 2 | 2-(trimethoxysilyl)ethyl benzene |
| SAM3 | 3 | n-propyl trimethoxysilane |
| SAM4 | 4 | Phenyl trimethoxysilane |

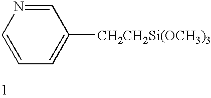

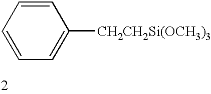

CH₃CH₂CH₂Si(OCH₃)₃
3

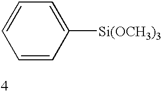

What is claimed is:

1. A diffusion barrier in an integrated circuit, wherein the diffusion barrier comprises a self-assembled monolayer.

2. The diffusion barrier according to claim 1, wherein the diffusion barrier is less than 5 nm thick.

3. The diffusion barrier according to claim 1, wherein the diffusion barrier is less than 2 nm thick.

4. The diffusion barrier according to claim 1, wherein the self-assembled monolayer contains an aromatic group at its terminus.

5. The diffusion barrier according to claim 1, wherein the diffusion barrier inhibits the diffusion of Cu into a silicon-based substrate.
